(19) United States
(12) Patent Application Publication
(10) Pub. No.: US 2025/0275197 A1
(43) Pub. Date: Aug. 28, 2025

(54) BACKSIDE GATE CONNECTOR

(71) Applicant: International Business Machines Corporation, Armonk, NY (US)

(72) Inventors: Min Gyu Sung, Latham, NY (US); Tao Li, Slingerlands, NY (US); Ruilong Xie, Niskayuna, NY (US); Albert M. Chu, Nashua, NH (US)

(21) Appl. No.: 18/589,755

(22) Filed: Feb. 28, 2024

(51) Int. Cl. H01L 29/06; H01L 21/8234; H01L 23/528; H01L 27/088; H01L 29/08; H01L 29/423; H01L 29/66; H01L 29/775; H01L 29/78; H01L 29/786

(52) U.S. Cl. CPC H10D 62/118; H01L 23/5286; H10D 30/014; H10D 30/024; H10D 30/43; H10D 30/62; H10D 30/6735; H10D 30/6757; H10D 62/151; H10D 64/017; H10D 84/0135; H10D 84/0149; H10D 84/038; H10D 84/834

(57) ABSTRACT

A semiconductor structure including a backside gate connector formed in a backside metal layer of the semiconductor structure. The backside gate connector directly contacts the bottom surface of two or more two gates where only a single gate contact connects one of the two or more gates to a layer of the front side interconnect wiring above the two or more gates. At least one source/drain residing between the two or more gates has a source/drain contact connecting a layer of the front side interconnect wiring. The backside gate connector connecting two or more gates resides below the two or more gates and any source/drains that are between the two or more gates.

### BACKGROUND

The disclosure generally relates to forming a semiconductor device and more particularly, to semiconductor devices connected to more than one layer of backside metal.

The amount of data we process is rapidly increasing at a rate higher than that of Moore's law. Increasing system performance requirements, driven at least in part by the increasing use of artificial intelligence, continue to drive tighter pitches in semiconductor devices and smaller semiconductor chips. With the evolution of reduced-size transistors, semiconductor technology has progressed from planar transistor designs to three-dimensional type finFET designs which are further evolving into nanosheet gate-all-around transistor (GAA FET) designs and stacked FETs to provide tighter pitches while improving semiconductor device performance.

The drive to the two-nanometer technology node has also initiated the emerging use of backside interconnect layers for a backside power delivery network. Creating backside interconnect layers below the front-end-of-line semiconductor devices provides improved power performance and more routing options for semiconductor devices. A backside power delivery network improves semiconductor device gate delay and relieves some of the BEOL wiring congestion on the front side of the semiconductor substrate.

### SUMMARY

The following presents a summary to provide a basic understanding of one or more embodiments of the disclosure. This summary is not intended to identify key elements or delineate any scope of the particular embodiments or any scope of the claims.

Aspects of the disclosed invention relate to a semiconductor structure that includes a backside gate connector in a backside metal layer directly contacting the bottom surface of at least two gates and a single gate contact directly contacts the top surface of one of the at least two gates, wherein the single gate contact connects one of the at least two gates to a layer of front side interconnect wiring above the at least two gates.

Aspects of the disclosed invention relate to a semiconductor structure including a backside gate connector in a backside metal layer directly contacting a bottom surface of at least two gates in more than one semiconductor device. The backside gate connector, composed of a contact metal, is below and between the least two gates in the more than one semiconductor device. A gate contact directly contacts a top surface of one of the at least two gates and connects the gate to a layer of the frontside interconnect wiring above the at least two gates.

Aspects of the disclosed invention include a method of forming a backside gate connector after front-end-of-line (FEOL) semiconductor fabrication processes, middle-of-line (MOL) semiconductor fabrication processes, backend-of-line semiconductor fabrication processes form a field-effect transistor, and carrier wafer attach. The method includes wafer flip and semiconductor substrate removal, using known semiconductor removal processes, the removal process stopping at the etch stop layer. The method includes etch stop layer removal followed by a partial removal of the semiconductor material below the semiconductor devices exposing the bottom surface of the placeholders. The method includes selectively removing the exposed placeholders under a protective layer below each of the source/drains of the removed placeholders. A deposition of the first dielectric material fills the holes under the source/drains created by the placeholder removal. Using one or more etching processes, the remaining semiconductor material is removed exposing a dielectric isolation layer under the active region of the semiconductor device and exposing the sidewalls of the first dielectric material. The method includes forming a dielectric liner over the sidewalls of the first dielectric material. The method includes depositing a second dielectric in the gaps between the dielectric liners. After patterning an etch mask, a first etching process removes a portion of the exposed second dielectric material, dielectric liner, and first dielectric material followed by a second etching process removing the remaining portion of the first dielectric material exposing the bottom of one of the source/drains. The method includes using a selective timed etching process to remove a top portion of the exposed portions of the second dielectric material, dielectric liner, and first dielectric material. Another selective etching process removes the second dielectric material exposing the bottom surface of two or more gates. The method includes depositing a contact metal on the backside of the semiconductor structure and planarizing to form a backside contact to a source/drain and a backside gate connector connecting the bottom surface of the two or more gates.

### BRIEF DESCRIPTION OF THE DRAWINGS

The above and other aspects, features, and advantages of various embodiments of the present invention will be more apparent from the following description taken in conjunction with the accompanying drawings.

FIG. 1 depicts a top view of an illustration of a semiconductor design, in accordance with an embodiment of the present invention.

FIG. 2 depicts a cross-sectional view of a semiconductor structure for a nanosheet field-effect transistor (FET) with at least two gate contacts and a source/drain contact connecting to one or more layers of the frontside interconnect wiring after carrier wafer bonding, in accordance with an embodiment of the present invention.

FIG. 3 depicts the cross-sectional view of the semiconductor structure after wafer flipping and substrate removal, in accordance with an embodiment of the present invention.

FIG. 4 depicts the cross-sectional view of the semiconductor structure after removing an etch stop layer and a portion of the semiconductor material, in accordance with an embodiment of the present invention.

FIG. 5 depicts the cross-sectional view of the semiconductor structures after depositing and patterning a layer of organic planarization layer (OPL) and removing exposed placeholders, in accordance with an embodiment of the present invention.

FIG. 6 depicts the cross-sectional view of the semiconductor structure after depositing a first dielectric fill, in accordance with an embodiment of the present invention.

FIG. 7 depicts the cross-sectional view of the semiconductor structure after removing the OPL, in accordance with an embodiment of the present invention.

FIG. 8 depicts the cross-sectional view of the semiconductor structure after depositing a dielectric liner and a second dielectric fill, in accordance with an embodiment of the present invention.

FIG. 9 depicts the cross-sectional view of the semiconductor structure after a second OPL deposit and patterning followed by a first etching process and a second etching process removing portions of the first dielectric fill, the dielectric liner, and the second dielectric fill, in accordance with an embodiment of the present invention.

FIG. 10 depicts the cross-sectional views of the semiconductor structures after removing the second OPL, depositing and patterning a third OPL, and removing exposed portions of the first dielectric fill, the dielectric liner, and the second dielectric fill, in accordance with an embodiment of the present invention.

FIG. 11 depicts the cross-sectional views of the semiconductor structures after a selective anisotropic etching process removes exposed portions of the first dielectric material, in accordance with an embodiment of the present invention.

FIG. 12 depicts the cross-sectional views of the semiconductor structures after removing the third OPL, forming backside vias, forming a backside contact, and forming a backside gate connector, in accordance with an embodiment of the present invention.

FIG. 13 depicts the cross-sectional views of the semiconductor structures after depositing a backside interlayer dielectric (ILD), a backside via, a backside power rail, and a backside power delivery network, in accordance with an embodiment of the present invention.

### DETAILED DESCRIPTION

Embodiments of the present invention recognize that in cases where there is a need to connect two nearby gates over an active region of the semiconductor chip, there is limited room for a source/drain contact to the middle-of-line (MOL) wiring above the semiconductor devices when the source/drain is between the nearby connected nearby gates. Embodiments of the present invention recognize that a semiconductor structure that provides a way for nearby gates to be connected without blocking any intervening source/drain contacts to the MOL wiring above the semiconductor devices would be desirable.

Aspects of the present invention provide a semiconductor structure and a method of forming the semiconductor structure with a backside gate connector. In aspects of the present invention, the backside gate connector uses the backside metallization below the semiconductor devices to form a backside connection to two or more gates. The backside gate connector is below the semiconductor devices and has a single contact or connection to the frontside device wiring or the MOL wiring that is above the semiconductor devices. Aspects of the present invention provide the backside gate connector that connects two or more gates formed on the device side or front side of the semiconductor chip to connect on the backside of the semiconductor chip using a single gate contact to the front side device wiring. Using the backside gate connector, the device side wiring above at least one of the backside connected gates is available for front side device wiring such as forming a source/drain contact between the nearby gates connected by the backside gate connector.

The present invention provides a backside gate connector formed below the semiconductor devices that directly contacts the bottom surface of two or more adjacent or nearby gates where only one of the gates contacted by the backside gate connector connects by a gate contact to the front side wiring above the semiconductor devices. In this way, when two or more gates are connected only a single gate contact connects to MOL wiring above the semiconductor devices. This reduces front side MOL and front side interconnect wiring congestion. The connection between the two or more gates can occur on the backside of the semiconductor structure under the semiconductor devices providing additional wiring area on the front side of the semiconductor structure above the semiconductor devices. For example, the backside gate connection created by the backside gate connector is placed right under the front side of source and drain contacts. In this way, the source, drains, and backside gate connector are placed vertically so that the device cell size can be reduced efficiently.

In embodiments, the backside connected gates are two or more adjacent gates, two or more non-adjacent gates, or three or more backside connected gates that are a combination of adjacent and non-adjacent gates are connected by the backside gate connector and where only one of the three or more backside connected gates has a gate contact connecting to the front side interconnect wiring layers above the semiconductor devices by one or more vias, contacts, and/or one or more metal layers.

Connecting two or more nearby gates by the backside gate connector which may be adjacent gates or gates in the same vicinity relieves blockages of the semiconductor area above one or more of the backside connected gates freeing up semiconductor real estate above the backside connected gates for additional front side wiring or connections. In aspects of the present invention, when two nearby gates need to be connected using the local backside connector, any source/drain residing between the backside connected gates can have a source/drain contact to front side wiring or MOL metal layers connections.

Embodiments of the present invention include a method to form a backside gate connector. After known front-end-of-line (FEOL) semiconductor processes, middle of line (MOL) semiconductor processes, and backend-of-line (BEOL) semiconductor processes including front side interconnect wiring formation and carrier wafer bonding, a wafer flip occurs. The semiconductor substrate is removed stopping at the etch stop layer. The method includes removing the etch stop layer and a portion of the semiconductor material below an isolation layer and the channels of semiconductor devices and below a protective layer under the source/drains.

The method includes removing some of the placeholders (e.g., typically, composed of SiGe) and depositing a first dielectric material in place of the removed placeholders, The first dielectric material and the semiconductor substrate are planarized by a chemical-mechanical polish (CMP). The method includes the complete removal of the remaining semiconductor material.

Using known spacer formation processes, a dielectric liner forms over the sidewalls of the first dielectric material. A second dielectric material is deposited in openings between the dielectric electric liners and a CMP occurs.

The remaining placeholder is removed. Using a patterned OPL, exposed portions of the second dielectric material and the isolation layer are removed to expose the bottom surface of two or more gates. The method includes depositing a contact metal to form a backside gate connector joining the bottom surfaces of the exposed gates and a backside contact to an exposed source/drain. Using known backside semiconductor processes, a backside interlayer dielectric is deposited over the semiconductor structure backside and a backside power rail forms contacting the backside contact to the source/drain. A backside power delivery network is formed under the backside power rail using known semiconductor processes.

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Some of the process steps, depicted, can be combined as an integrated process step. In addition, descriptions of well-known functions and constructions may be omitted for clarity and conciseness.

The terms and words used in the following description and claims are not limited to the bibliographical meanings but are merely used to enable a clear and consistent understanding of the invention. Accordingly, it should be apparent to those skilled in the art that the following description of exemplary embodiments of the present invention is provided for illustration purposes only and not for the purpose of limiting the invention as defined by the appended claims and their equivalents.

It is to be understood that the singular forms “a,” “an,” and “the” include plural referents unless the context dictates otherwise. Thus, for example, reference to “a component surface” includes reference to one or more of such surfaces unless the context dictates otherwise.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “on”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” or “contact” means that a first element, such as a first structure, and a second element, such as a second structure, are connected without any intermediary conducting, insulating, or semiconductor layers at the interface of the two elements.

In the interest of not obscuring the presentation of embodiments of the present invention, in the following detailed description, some processing steps or operations that are known in the art may have been combined for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Detailed embodiments of the claimed structures and methods are disclosed herein. The method steps described below do not form a complete process flow for manufacturing integrated circuits on semiconductor chips. The present embodiments can be practiced in conjunction with the integrated circuit fabrication techniques for semiconductor chips and devices currently used in the art, and only so much of the commonly practiced process steps are included as are necessary for an understanding of the described embodiments. The figures represent cross-section portions of a semiconductor chip or a substrate, such as a semiconductor wafer during fabrication, and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment,” etc., indicate that the embodiment described may include a particular feature, structure or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Reference will now be made in detail to the embodiments of the present invention, examples of which are illustrated in the accompanying drawings, wherein like reference numerals refer to like elements throughout.

Deposition processes for materials, such as metal materials, dielectric materials, and sacrificial materials include but are not limited to chemical vapor deposition (CVD), physical vapor deposition (PVD), atomic layer deposition (ALD), molecular layer deposition (MLD), high-density plasma (HDP) deposition, or gas cluster ion beam (GCIB) deposition. Variations of CVD processes include but are not limited to, atmospheric pressure CVD (APCVD), low-pressure CVD (LPCVD), plasma enhanced CVD (PECVD), and metal-organic CVD (MOCVD), and combinations thereof may also be employed.

Removal, removing, or etching as used herein includes but is not limited to patterning using one of lithography, photolithography, an extreme ultraviolet (EUV) lithography process, or any other known semiconductor patterning process followed by one or more etching processes. Some examples of etching processes include but are not limited to the following processes, such as a dry etching process using a reactive ion etch (RIE) or ion beam etch (IBE), a wet chemical etch process, or a combination of these etching processes.

Reference is now made to the figures. The figures provide schematic cross-sectional illustrations of semiconductor devices at intermediate stages of fabrication, according to one or more embodiments of the invention. The device provides schematic representations of the devices of the invention and is not to be considered accurate or limiting with regard to device element scale.

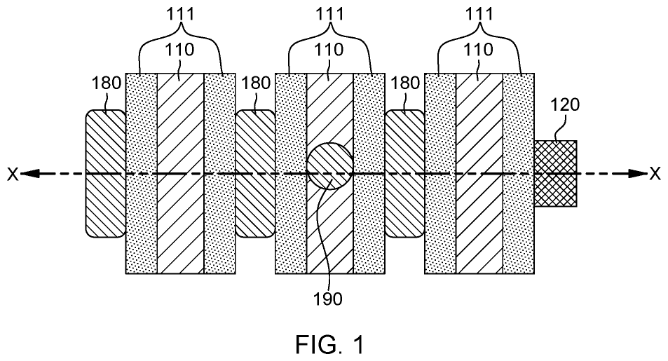

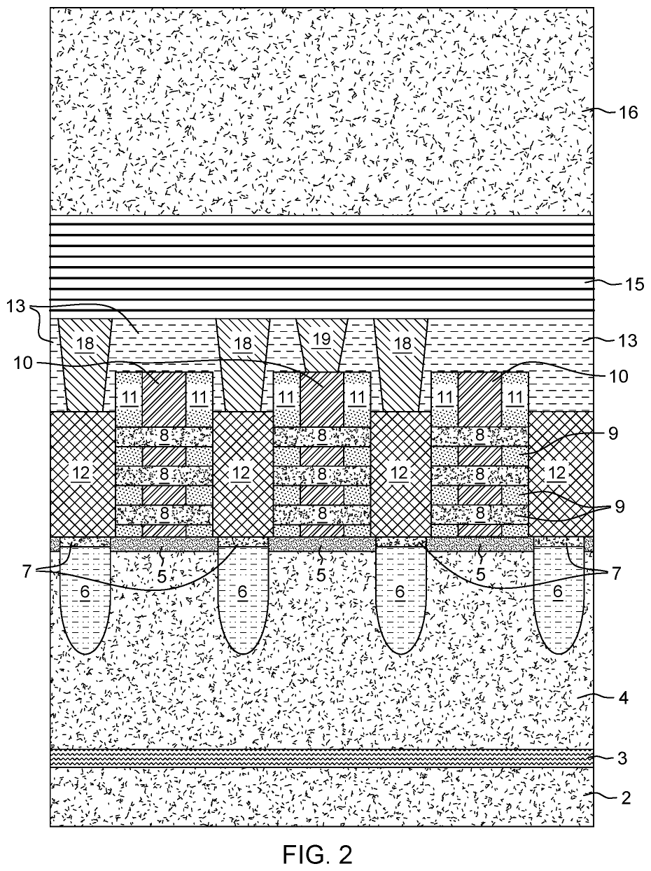

FIG. 1 depicts a top view of an illustration of a semiconductor design, in accordance with an embodiment of the present invention. Also, illustrated in FIG. 1 is the location of the cross-sectional views X-X depicted in FIG. 2-FIG. 13. The semiconductor design depicted in FIG. 1 has three gates 110, each with gate spacers 111, one gate contact 190 connecting to the middle gate of gates 110, three source/drain contacts 180, and active region 120. As known to one skilled in the art, in other semiconductor designs, more than three gates 10, more than one gate contact 190, and more than three source/drain contacts 180 can be formed. In FIG. 1, the three source/drain contacts 180 are directly adjacent to and between two adjacent gates 110.

FIG. 2 depicts a cross-sectional view of a semiconductor structure for three nanosheet field-effect transistors (GAA FET) composed of channels 8, gates 10, gate spacers 11, inner spacers 9, and source/drains 12 after front-end-of line (FEOL) semiconductor device formation, middle-of-line (MOL) fabrication processes, backend-of line (BEOL) processes forming frontside interconnect wiring 15, and carrier wafer 16 bonding with at least two gate contacts and a source/drain contact connecting to one or more layers of the frontside interconnect wiring after carrier wafer bonding, in accordance with an embodiment of the present invention. Also, depicted in FIG. 2 are substrate 2, etch stop 3 under semiconductor material 4, isolation layer 5 under gates 10 with gate spacers 11, placeholders 6, and protective layer 7 between each of placeholders 6 and source/drains 12. In various embodiments, protective layer 7 is silicon but can be another semiconductor material in other embodiments. In other embodiments, the semiconductor structure includes two or more finFETs, stacked FETs, complementary FETs (CFETs), planar FETs, complementary metal-oxide semiconductor (CMOS) devices, three-dimensional stacked CMOS, or other types of logic devices.

Using known FEOL, MOL, and BEOL processes, the semiconductor structure of FIG. 2 can have a placeholder 6 under each of source/drains 12 and source/drain contacts 18 connecting source/drains 12 to frontside interconnect wiring 15 (e.g., three source/drain contacts 18 connect to frontside interconnect wiring 15). As known to one skilled in the art, source/drain contacts 18 and gate contact 19 can be formed in one or more layers of the MOL metal layers. One gate contact 19 connects the middle gate of gates 10 to frontside interconnect wiring 15. As known to one skilled in the art, gates 10 can include a gate dielectric (not depicted) and gates 10 can be composed of one or more work function metals as a gate electrode along with gate spacer 11 and inner spacers 9.

Placeholders 6 can be composed of a semiconductor material such as, but not limited to, SiGe. Protective layer 7 typically is silicon (Si), however, other semiconductor material(s) may compose protective layer 7. While the semiconductor structure of FIG. 1 is depicted as a gate-all-around field-effect transistor (GAA FET), in other embodiments, the semiconductor structure can be a different logic device structure. For example, the semiconductor structure of FIG. 1 could depict two or more stacked FETs, a finFET, a complimentary FET, or another type of logic device.

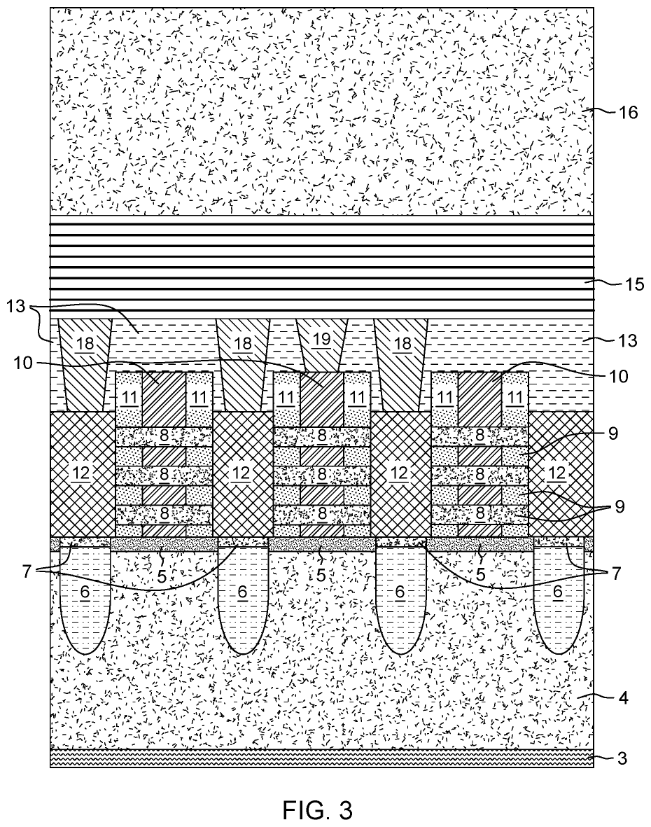

FIG. 3 depicts the cross-sectional view of the semiconductor structure after wafer flipping and substrate 2 removal, in accordance with an embodiment of the present invention. As depicted, FIG. 3 includes the elements of FIG. 2 without substrate 2. Using one or more of known wafer backside grinding and/or a wet semiconductor etching processes, substrate 2 is removed exposing etch stop 3.

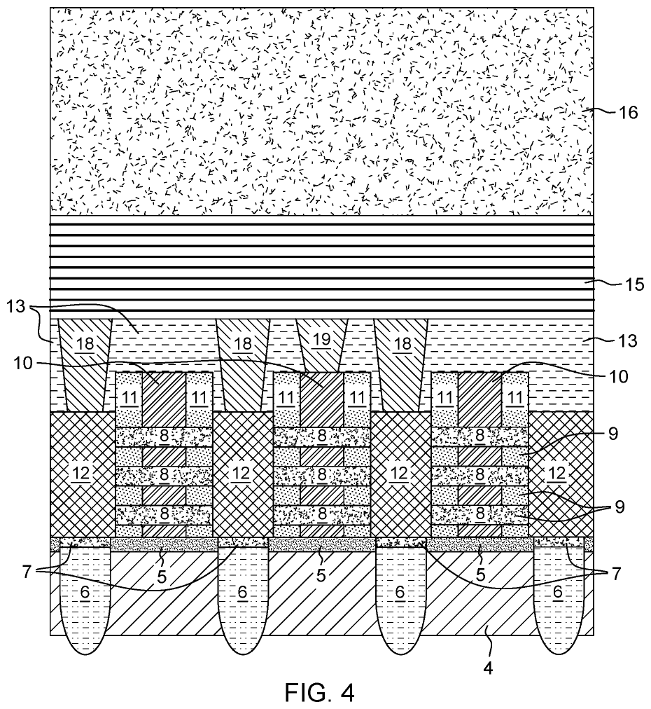

After wafer flipping, substrate 2 is the top surface of the semiconductor structure, FIG. 3 depicts the semiconductor structure as not flipped (e.g., substrate 2 under etch stop 3 and etch stop 3 is on bottom and exposed after substrate 2 removal in FIG. 3). FIGS. 4-13 are also depicted as not flipped.

FIG. 4 depicts the cross-sectional view of the semiconductor structure after removing etch stop 3 and a portion of semiconductor material 4, in accordance with an embodiment of the present invention. Using known etch stop removal processes (e.g., a wet or dry etching process for SiGe as etch stop 3), etch stop 3 is removed exposing the bottom surface of semiconductor material 4. A second semiconductor dry or wet etching process selective to semiconductor material 4 removes the bottom portion of semiconductor material 4 exposing the bottom surfaces of placeholders 6 and a portion of semiconductor material 4 around placeholders 6.

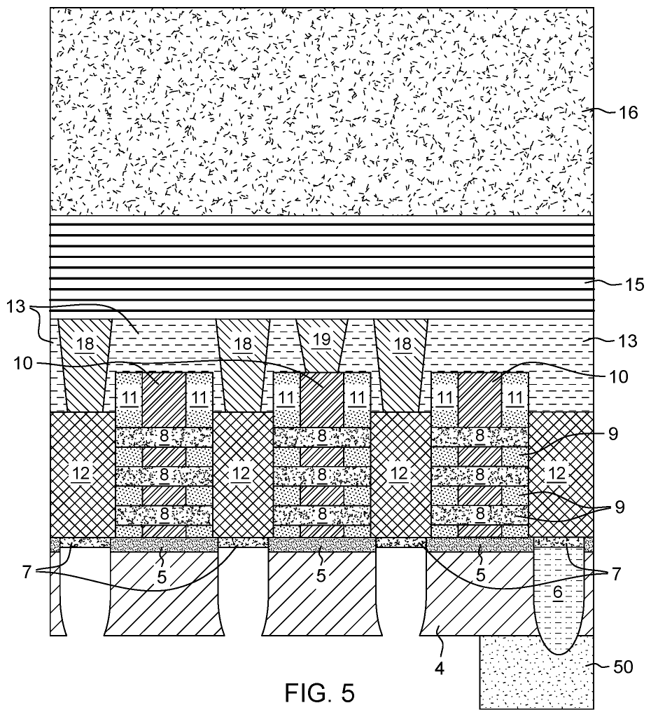

FIG. 5 depicts the cross-sectional view of the semiconductor structures after depositing and patterning OPL 50 and removing the exposed placeholders 6, in accordance with an embodiment of the present invention. OPL 50 is patterned to cover the rightmost portion of semiconductor material 4 and the rightmost placeholder 6. After patterning OPL 50, an etching process (e.g., RIE or a wet etching process) selectively removes the three exposed placeholders 6 exposing protective layer 7 along with some sidewalls of semiconductor material 4 adjacent to the removed placeholders 6. As depicted, semiconductor material 4 remains along with one placeholder 6 covered by OPL 50.

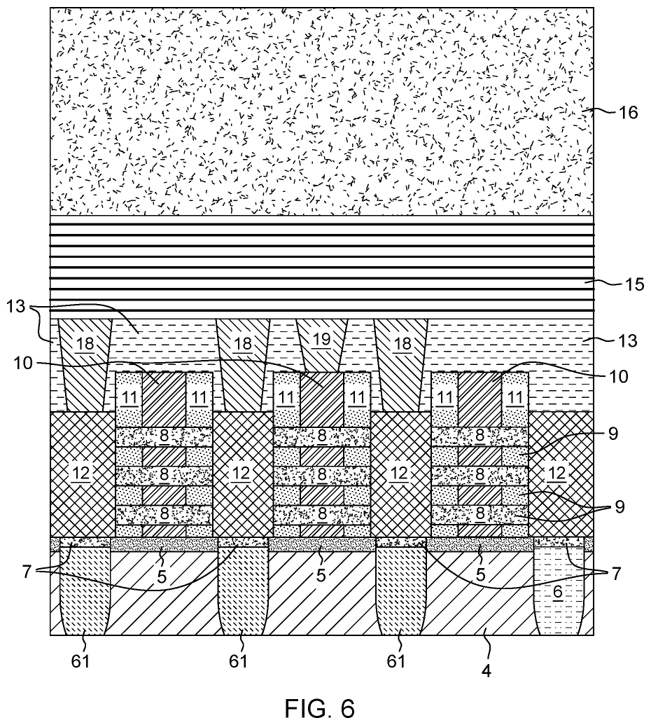

FIG. 6 depicts the cross-sectional view of the semiconductor structure after removing OPL 50 and depositing first dielectric material 61, in accordance with an embodiment of the present invention. Using known semiconductor processes such as an OPL ash and/or wet etching, OPL 50 can be removed.

A layer of first dielectric material 61 is deposited over the semiconductor structure (e.g., by ALD, CVD, or PVD) filling the holes created by the removal of some of placeholders 6. First dielectric material 61 replaces the removed placeholders 6. As depicted, first dielectric material 61 contacts the bottom of protective layer 7. In various embodiments, first dielectric material 61 is a dielectric material such as, but not limited to, SiO₂. A chemical-mechanical polish (CMP) planarizes the surface and removes excess first dielectric material 61 over semiconductor material 4.

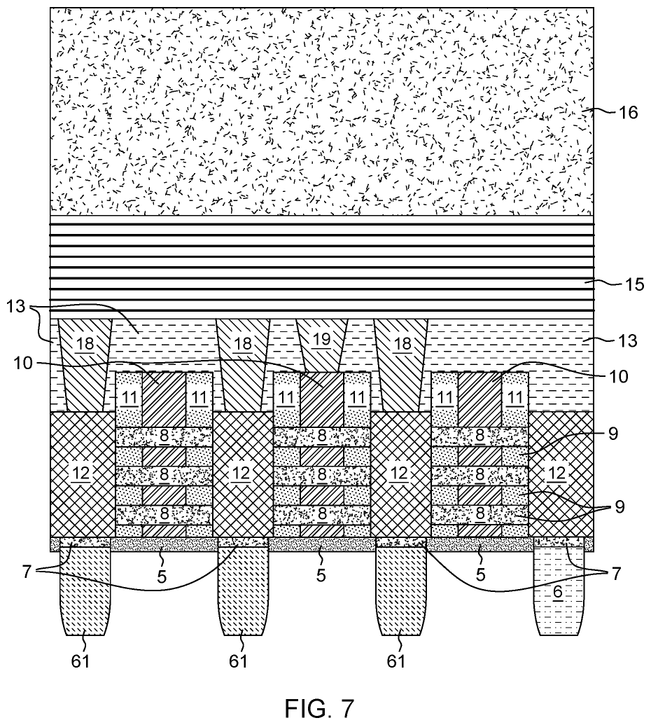

FIG. 7 depicts the cross-sectional view of the semiconductor structure after removing semiconductor material 4, in accordance with an embodiment of the present invention. Using one or more known semiconductor material dry or wet etching processes, semiconductor material 4 is removed, exposing first dielectric material 61, isolation layer 5, and the remaining placeholder 6.

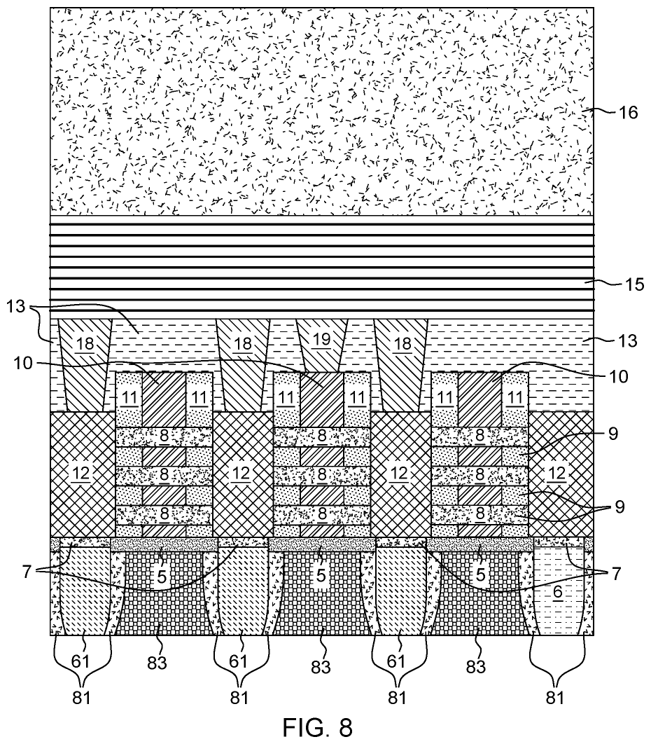

FIG. 8 depicts the cross-sectional view of the semiconductor structure after depositing dielectric liner 81 and a second dielectric 83, in accordance with an embodiment of the present invention. Using known deposition processes (e.g., ALD), dielectric liner 81 is deposited over the semiconductor structure. Dielectric liner 81 can be composed of SiCO but is not limited to this dielectric material. Dielectric liner 81 deposits on first dielectric material 61 and isolation layer 5. A directional etching process such as RIE can remove horizontal portions of dielectric liner 81.

A second deposition process (e.g., ALD or CVD), deposits second dielectric 83 on isolation layer 5 and first dielectric material 61. Second dielectric 83 can be composed of a nitride but is not limited to these dielectric materials. A CMP can planarize the surface of the semiconductor structure.

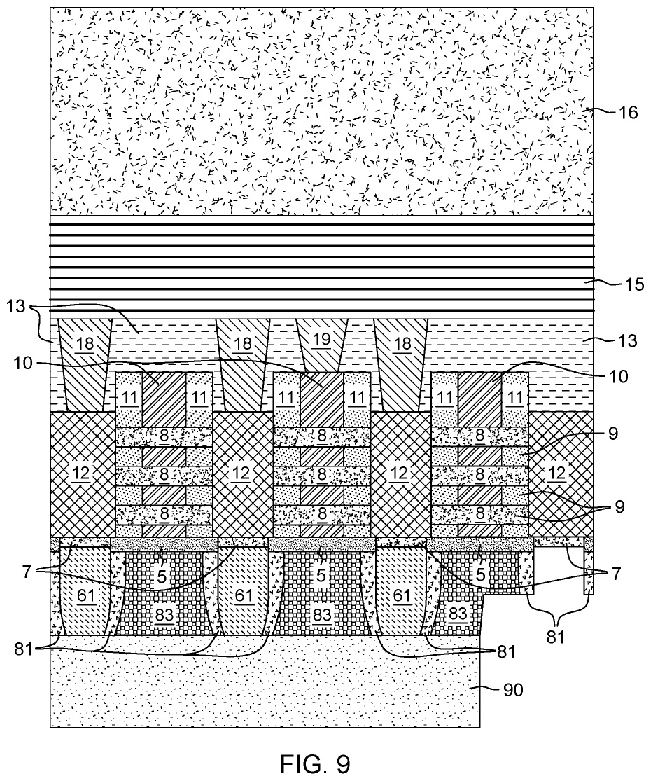

FIG. 9 depicts the cross-sectional view of the semiconductor structure after OPL 90 deposition and patterning followed by a first etching process and a second etching process in accordance with an embodiment of the present invention. As depicted, FIG. 9 includes the elements of FIG. 8 with patterned OPL 90 and without the remaining placeholder 6 and portions of liner 81 and second dielectric 83.

The first etching process, which can be a timed wet etching process, removes the exposed bottom portion of liner 81 and second dielectric 83. In FIG. 9, approximately one-half of the thickness of the exposed portions of liner 81 and second dielectric 83 are removed but other examples may remove more or less of dielectric liner 81 and second dielectric 83.

A second etching process, selective to a semiconductor material such as SiGe, removes the remaining portion of placeholder 6. The second etching process, selective to placeholder 6 material, stops at protective layer 7 under gates 10 and exposes the inside of the sidewalls of liner 81. The opening etched can be a backside contact opening or a via hole.

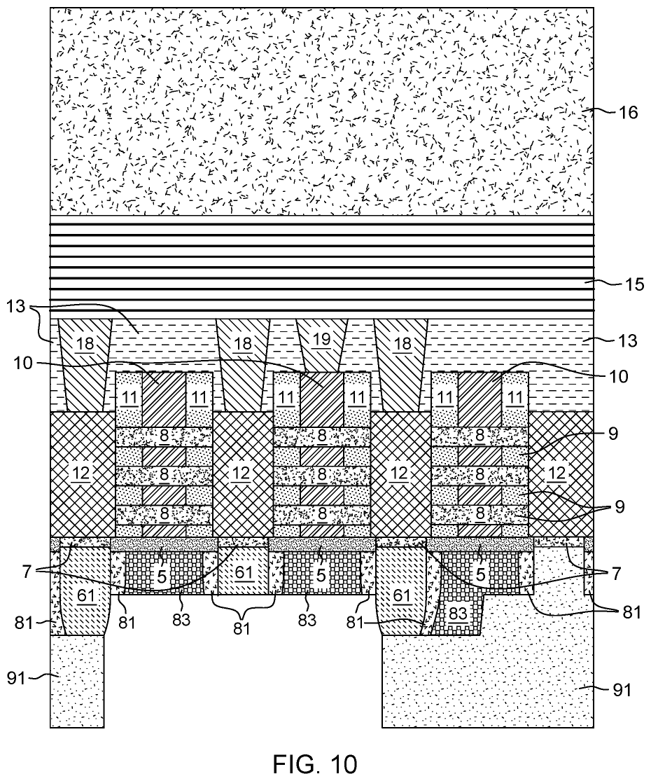

FIG. 10 depicts the cross-sectional views of the semiconductor structures after removing OPL 90, depositing, and patterning OPL 91, and removing exposed portions of first dielectric material 61, liner 81, and second dielectric 83, in accordance with an embodiment of the present invention.

After removing OPL 90 and patterning OPL 91 after OPL 91 deposition, a timed non-selective etching process (e.g., RIE) or a timed wet etching process, removes a portion of the exposed bottom portions of first dielectric material 61, liner 81, and second dielectric 83. For example, as depicted in FIG. 10, approximately one-half of the exposed portions of the three dielectric materials are removed although in other examples more or less of the three dielectric materials can be removed. The removed portions of the three dielectric materials include two portions of second dielectric 83 below isolation layer 5 that is below two adjacent gates 10. The opening created by the non-selective etching process extends at least between four of dielectric liners 81 that are around the two portions of second dielectric 83. In other embodiments, three or more portions of adjacent second dielectric 83 are exposed and more of liners 81 are removed.

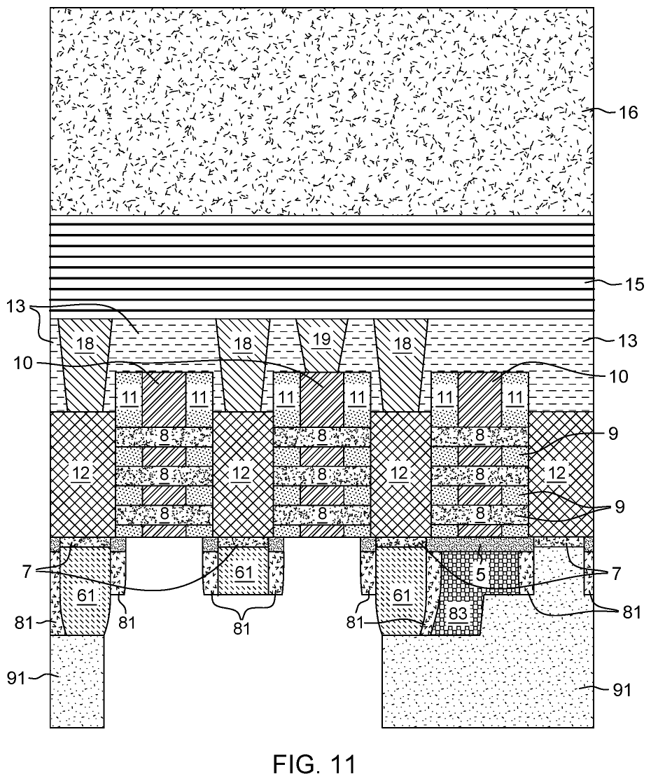

FIG. 11 depicts the cross-sectional views of the semiconductor structures after a selective etching process removes exposed portions of first dielectric material 61 and isolation layer 5, in accordance with an embodiment of the present invention. For example, using a selective dry etching process (e.g., RIE), the exposed portions of first dielectric material 61 and isolation layer 5 are removed. After etching, the bottom surfaces of two adjacent gates 10 are exposed.

In some examples, more than two adjacent portions of first dielectric material 61 are removed exposing more than two bottom surfaces of gates 10. In other examples, two or more non-adjacent portions of first dielectric material 61 are exposed and removed. In these examples, the bottom surfaces of two or more non-adjacent gates 10 can be exposed. In yet another example, a combination of two or more adjacent first dielectric material 61 and at least one or more of non-adjacent portions of first dielectric material 61 are removed to expose the bottom surfaces of two or more adjacent gates 10 and at least one or more non-adjacent gates 10. In various embodiments, the two or more bottom surfaces of two or more gates of gates 10 include gates 10 in more than one semiconductor device.

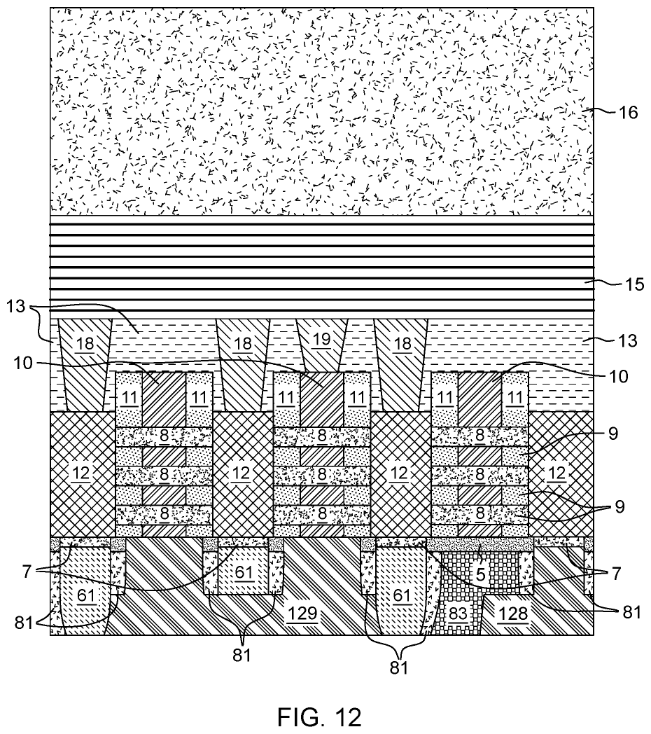

FIG. 12 depicts the cross-sectional views of the semiconductor structures after removing OPL 91 and forming backside contact 128 and backside gate connector 129, in accordance with an embodiment of the present invention.

After removing OPL 91 using known OPL removal processes, backside contact 128 and backside gate connector 129 can formed using known contact formation processes. For example, a contact metal such as W, Co, Cu, or Ru is deposited by CVD, PVD, ALD, or electroplating on the exposed bottom surfaces of gates 10, the rightmost source/drain 12, portions of liners 81, first dielectric material 61, and second dielectric 83. The deposition of the contact metal on protective layer 7 (e.g., silicon) fills the opening under the rightmost source/drain 12 and forms backside contact 128. As depicted, backside contact 128 connects to the rightmost source/drain 12 through protective layer 7 after a CMP.

The deposition of the contact metal on the two exposed surfaces of gates 10 fills the opening that extends between the two bottom surfaces of gates 10 to form backside gate connector 129 after the CMP. One of gates 10 (the rightmost in FIG. 12) contacts by backside gate connector 129 and connects by gate contact 19 to front side interconnect wiring 15. The second of gates 103 contacted by backside gate connector 129 does not connect directly by a gate contact to front side interconnect wiring 15. In this way, the space above the second or leftmost of gates 33 connected to local gate connector 129 is available for front side wiring and/or additional front side connections or contacts. As known to one skilled in the art, in other examples, gate contact 190 connects to one or more metal layers or vias in the MOL wiring before connecting to front side interconnect wiring 15.

As depicted in FIG. 12, backside gate connector 129 can have two vertical elements where each vertical element contacts the bottom surface of one of gates 10. The top portion of the sidewall of each of the vertical elements is surrounded by isolation layer 7 and dielectric liner 81 on the bottom portion of the vertical element. As depicted, backside gate connector 129 has a horizontal element connecting each of the two vertical elements where the top surface is covered by a portion of each of liner 81 around the sidewall of the vertical elements and first dielectric material 61. The horizontal portion of backside gate connector 129 is under source/drain 12 which is between the two gates 10 connected to backside gate connector 129. One of source/drain contacts 18 connects to the top surface of the source/drain 12 which is between the two gates 10 connected to backside gate connector 129. In other embodiments, more than two vertical elements of backside gate connector 129 connect to more than two of gates 10 where gates 10 can be two or more adjacent gates 10, two or more non-adjacent gates 10, or a combination of adjacent and non-adjacent gates 10. Accordingly, the more than two vertical portions of backside gate connector 129 connect to a horizontal portion of backside gate connector 129. In these embodiments, more than two of source/drain contacts 18 can connect to front side interconnect wiring 15. In other words, backside gate connector 129 resides under at least two of gates 10 and under one or more of source/drains 12 residing between the gates 10. In an embodiment, the more than two source/drain 18 reside in two or more different semiconductor devices (e.g., two GAA FETs or in two different types of logic devices).

While FIG. 11 depicts backside gate connector 129 connecting two adjacent gates 10 in a GAA FET, in other embodiments, backside gate connector 129 connects gates 10 of two or more semiconductor devices such as two or more of gates 10 in two GAA FETs. In one embodiment, backside gate connector 129 connects two or more gates in at least two different types of semiconductor devices (e.g., two logic devices such as a GAA FET and a planar FET).

As discussed above, using the methods of the present invention described in detail above, backside gate connectors similar to backside gate connector 129 can be formed joining more than two adjacent gates 10 formed on the front side of the semiconductor substrate. Additionally, using additional patterning of an OPL and etching processes, two or more non-adjacent gates 10 formed on the front side of the semiconductor substrate can be connected by a similar backside gate connector as described above that contacts the two or more non-adjacent gates 33 formed by the front-end of line (FEOL) processes on the front side of the semiconductor substrate. In these embodiments, the two or more non-adjacent gates 10 formed by FEOL processes are connected by backside gate connector 129 formed in one or more of the backside metal layers of the semiconductor structure or semiconductor chip. Connecting two or more of gates 10 formed on the front side of the semiconductor structure of FIG. 12 using portions of the backside metal layers and/or backside contacts provides more space for one or more of front side semiconductor device wiring, source/drain contacts, via connections, or tighter packing of front side semiconductor devices (e.g., smaller device pitches).

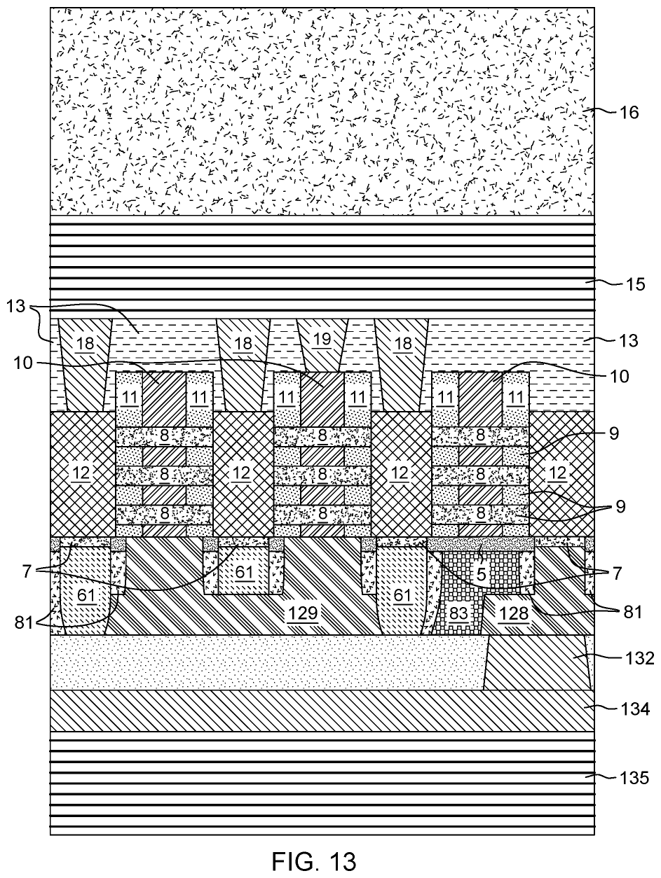

FIG. 13 depicts the cross-sectional views of the semiconductor structures after depositing backside ILD 131, backside via 132, backside power rail 134, and backside power delivery network 135, in accordance with an embodiment of the present invention.

Using a known deposition process such as CVD, backside ILD 131 can be deposited on backside gate connector 129 and the exposed surfaces of first dielectric material 61, dielectric liner 81, and second dielectric 83. Using known backside semiconductor fabrication processes, backside via 132 can be formed connecting to backside power rail 134. Backside power delivery network 135 can be formed below and directly connecting to backside power rail 134. As depicted, backside ILD 131 is between and separates backside gate connector 129 from backside power rail 134.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a backside gate connector in a backside metal layer contacting a bottom surface of at least two gates; and
a single gate contact directly contacts a top surface of one of the at least two gates, wherein the single gate contact connects the one of the at least two gates to a layer of front side interconnect wiring above the at least two gates.

2. The semiconductor structure of claim 1, wherein the at least two gates are in a gate-all-around field-effect transistor.

3. The semiconductor structure of claim 1, wherein the at least two gates are at least two adjacent gates contacting the backside gate connector.

4. The semiconductor structure of claim 1, wherein the at least two gates are at least two non-adjacent gates contacting the backside gate connector.

5. The semiconductor structure of claim 1, wherein the at least two gates are a combination of adjacent and non-adjacent gates contacting the backside gate connector.

6. The semiconductor structure of claim 1, further comprising at least one source/drain contact residing between the at least two gates, wherein the at least one source/drain contact is connected to the front side interconnect wiring above the at least one source/drain.

7. The semiconductor structure of claim 6, the backside gate connector resides under the at least two gates and the at least one source/drain.

8. The semiconductor structure of claim 1, further comprising:
a second source/drain adjacent to one of the at least two gates, wherein the second source/drain contact contacting the backside gate connector; and
a backside contact connects the second source/drain to a backside power rail.

9. The semiconductor structure of claim 1, wherein the backside gate connector resides on a backside interlayer dielectric with sidewalls surrounded by one or more dielectric materials.

10. The semiconductor structure of claim 9, wherein the backside interlayer dielectric separates the backside gate connector from the backside power rail.

11. The semiconductor structure of claim 1, wherein the backside gate connector further comprises:
two or more vertical elements of the backside gate connector contacting the bottom surface of each of the at least two gates; and
a horizontal element contacting, and between, each of the two of more vertical elements of the backside gate connector, wherein the horizontal element is: below the at least one source/drain, below each of the at least two gates, and above a portion of a backside power rail.

12. The semiconductor structure of claim 11, wherein the two of more vertical elements of the backside gate connector contacting the bottom surface of each of the at least two gates include a sidewall directly contacting a dielectric liner on a portion of the horizontal element.

13. The semiconductor structure of claim 12, wherein:
a top surface of the horizontal element is between each vertical element and directly under one or more dielectric materials; and
the horizontal element is directly on a backside interlayer dielectric.

14. A semiconductor structure comprising:
a backside gate connector contacting a bottom surface of at least two gates in more than one semiconductor device, wherein the backside gate connector is composed of a contact metal and is below and between the at least two gates in the more than one semiconductor device; and
a gate contact directly contacting a top surface of one of the at least two gates, wherein the gate contact connects the one of the at least two gates to a layer of front side interconnect wiring above the at least two gates.

15. The semiconductor structure of claim 14, wherein the more than one semiconductor device are each selected from the group consisting of gate-all-around field-effect transistors (GAA FETs), finFETs, stacked FETs, complementary FETs (CFETs), complementary metal-oxide semiconductor (CMOS) devices, and planar FETs.

16. A method of forming a backside gate connector comprising:
performing front-end-of-line, middle of line, backend-of-line semiconductor fabrication processes, and a carrier wafer attach for a gate-all-around semiconductor device;
flipping the wafer;
using a wafer grinding process and a wet etch to remove a semiconductor substrate;
removing an etch stop layer;
removing a portion of a semiconductor material exposing a bottom surface of a plurality of placeholders;
subsequent to patterning a first etch mask, removing exposed placeholders of the plurality of placeholders;
depositing a first dielectric material;
removing a remaining portion of the semiconductor material;
forming a dielectric liner around the first dielectric material;
depositing a second dielectric material contacting an isolation layer directly under each of three gates;
patterning a second etch mask to remove portions of the dielectric liner, the second dielectric material, and first dielectric material exposing a protective layer directly under a first source/drain;
patterning a third etch mask to remove exposed portions of the dielectric liner, the second dielectric material, and the first dielectric material exposing two gates;
depositing a contact metal on the exposed protective layer under the first source/drain and the two gates; and
planarizing the contact metal to form a backside gate connector connecting the two gates and a backside contact to the source/drain.

17. The method of claim 16, further comprising:
depositing a backside interlayer dielectric, wherein the backside interlayer dielectric is under the backside gate connector; and
forming a backside power rail connecting to the backside contact and a backside power delivery network.

18. The method of claim 16, wherein a second source/drain residing between the two gates connected to the backside gate connector includes a source/drain contact formed during the middle of line semiconductor fabrication processes.

19. The method of claim 16, wherein patterning the third etch mask to remove the exposed portions of the dielectric liner, the second dielectric material, and the first dielectric material exposing the two gates further comprises exposing more than two gates.

20. The method of claim 16, wherein depositing the contact metal further comprises depositing the contact metal on more than one of the first source/drains and more than the two gates.
